(19) United States
(12) Patent Application Publication
(10) Pub. No.: US 2021/0320225 A1
(43) Pub. Date: Oct. 14, 2021

(54) CHIP TRANSFERRING METHOD AND LED CHIP STRUCTURE

(71) Applicant: ASTI GLOBAL INC., TAIWAN, Taichung City (TW)

(72) Inventor: CHIEN-SHOU LIAO, New Taipei City (TW)

(21) Appl. No.: 17/225,064

(22) Filed: Apr. 7, 2021

(30) Foreign Application Priority Data
Apr. 8, 2020 (TW) 109111731

(51) Int. Cl. H01L 33/38; H01L 33/00; H01L 33/64; H01L 33/48; H01L 33/62

(52) U.S. Cl. CPC H01L 33/382; H01L 33/005; H01L 33/644; H01L 2933/0016; H01L 33/62; H01L 2933/0075; H01L 33/486

(57) ABSTRACT

A chip transferring method and an LED chip structure are provided. The chip transferring method includes distributing a plurality of LED chip structures in a liquid substance of a liquid receiving tank, each LED chip structure including an LED chip, a metal material layer and a removable connection layer; placing a carrier substrate in the liquid receiving tank, the carrier substrate including a carrier body for carrying a plurality of hot-melt material layers and a plurality of micro heaters disposed on the carrier body; respectively melting the hot-melt material layers by the micro heaters, so that the metal material layer of each LED chip structure is adhered to the corresponding hot-melt material layer that has been melted; separating the carrier substrate with the LED chip structures from the liquid receiving tank; and transferring the LED chip structures from the carrier substrate to an adhesive substrate.

### CROSS-REFERENCE TO RELATED PATENT APPLICATION

This application claims the benefit of priority to Taiwan Patent Application No. 109111731, filed on Apr. 8, 2020. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a chip transferring method and a chip structure, and more particularly to an LED (light emitting diode) chip transferring method and an LED chip structure.

### BACKGROUND OF THE DISCLOSURE

Currently, an LED chip is usually transferred from a carrier to a circuit board by a nozzle, but such a chip transferring method still has room for improvement.

### SUMMARY OF THE DISCLOSURE

In response to the above-referenced technical inadequacy, the present disclosure provides a chip transferring method and an LED chip structure.

In one aspect, the present disclosure provides a chip transferring method that includes: distributing a plurality of LED chip structures in a liquid substance of a liquid receiving tank, in which each of the LED chip structures includes an LED chip, a metal material layer and a removable connection layer connected between the LED chip and the metal material layer; placing a carrier substrate in the liquid receiving tank, in which the carrier substrate includes a carrier body for carrying a plurality of hot-melt material layers and a plurality of micro heaters disposed on or inside the carrier body; respectively melting the hot-melt material layers by heating of the micro heaters, so that the metal material layer of each of the LED chip structures is adhered to the corresponding hot-melt material layer that has been melted; separating the carrier substrate with the LED chip structures from the liquid receiving tank; and transferring the LED chip structures from the carrier substrate to an adhesive substrate.

In another aspect, the present disclosure provides an LED chip structure including an LED chip, a removable connection layer and a metal material layer. The LED chip has at least one electrode contact disposed thereon. The removable connection layer is disposed on the LED chip. The metal material layer is disposed on the removable connection layer.

Therefore, the LED chip structures can be transferred from the liquid receiving tank to the circuit substrate by cooperation of the carrier substrate and the adhesive substrate, and the metal material layers can be respectively separated from the LED chips following (or by) the removal of the removable connection layers. In addition, the micro heaters can be turned on to respectively melt the hot-melt material layers, so that the metal material layers of the LED chip structures can be respectively adhered to the hot-melt material layers.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a chip transferring method according to a first embodiment of the present disclosure;

FIG. 2 is a schematic view of step S100 of the chip transferring method according to the first embodiment of the present disclosure;

FIG. 3 is a schematic view of an LED chip structure according to the present disclosure;

FIG. 4 is a schematic view of another LED chip structure according to the present disclosure;

FIG. 5 is a functional block diagram of a plurality of micro heaters and a plurality of power control switches according to the present disclosure;

FIG. 6 is a schematic view of a carrier substrate placed in a liquid receiving tank and a plurality of LED chip structures being adhered to the carrier substrate according to the present disclosure;

FIG. 7 is a schematic view of the LED chip structure being moved a position above an adhesive substrate by adhering of the carrier substrate according to the present disclosure;

FIG. 8 is a schematic view of step S102 of the chip transferring method according to the first embodiment of the present disclosure;

FIG. 9 is a schematic view of the carrier substrate being separated from the LED chip structure according to the present disclosure;

FIG. 10 is a schematic view of step S104 of the chip transferring method according to the first embodiment of the present disclosure;

FIG. 11 is a schematic view of both a removable connection layer and a metal material layer being removed from the LED chip structure according to the present disclosure;

FIG. 12 is a schematic view of each of the LED chips being classified according to positions of a first electrode contact and a second electrode contact according to the present disclosure;

FIG. 13 is a schematic view of step S106 of the chip transferring method according to the first embodiment of the present disclosure;

FIG. 14 is a functional block diagram of a plurality of micro heaters and a power control switch according to the present disclosure;

FIG. 15 is a schematic view of a plurality of red LED chip structures being respectively adhered to a plurality of first hot-melt material layers according to the present disclosure;

FIG. 16 is a schematic view of a plurality of green LED chip structures being respectively adhered to a plurality of second hot-melt material layers according to the present disclosure; and

FIG. 17 is a schematic view of a plurality of blue LED chip structures being respectively adhered to a plurality of third hot-melt material layers according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

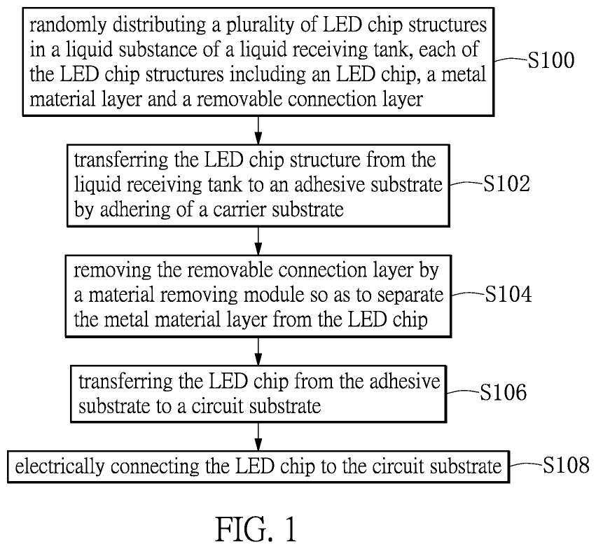

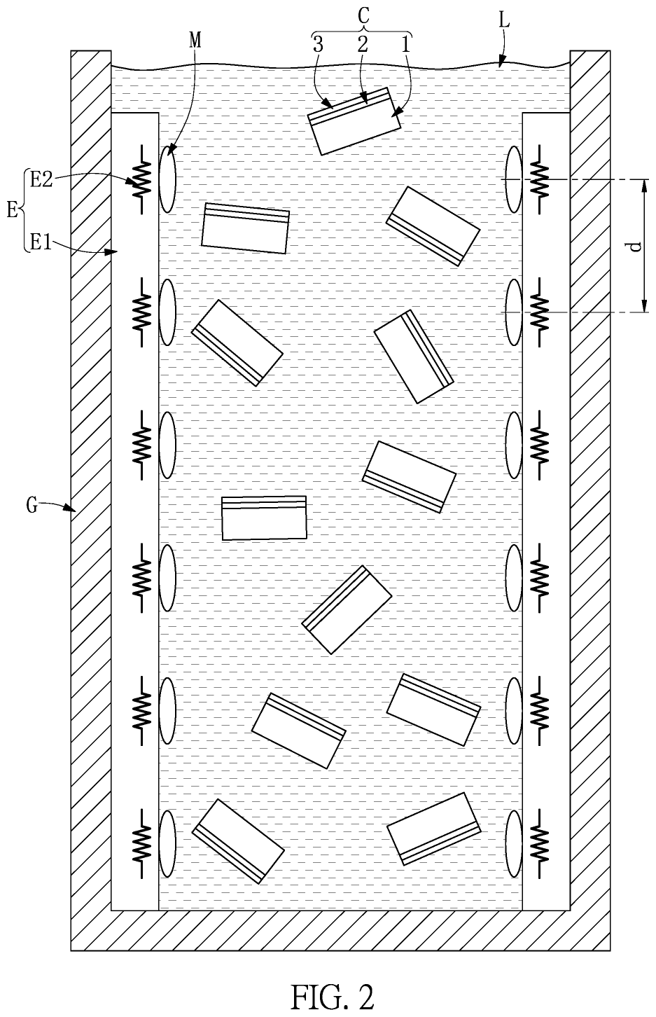

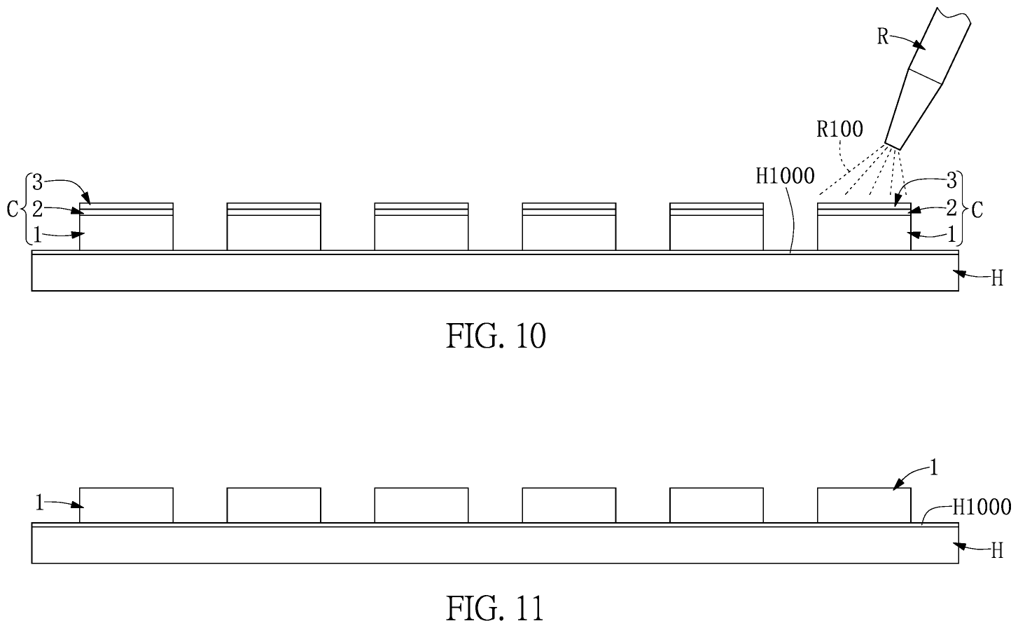

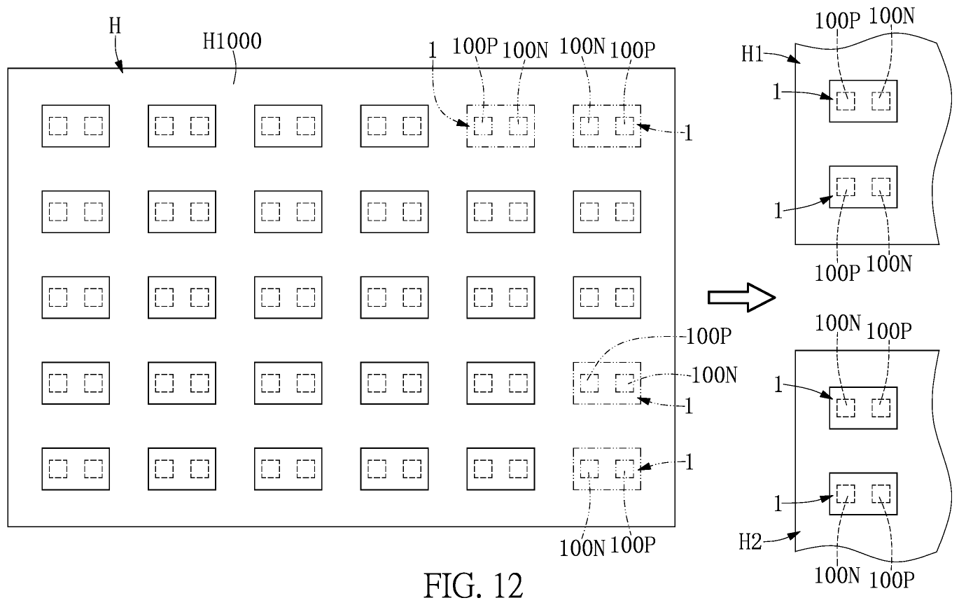

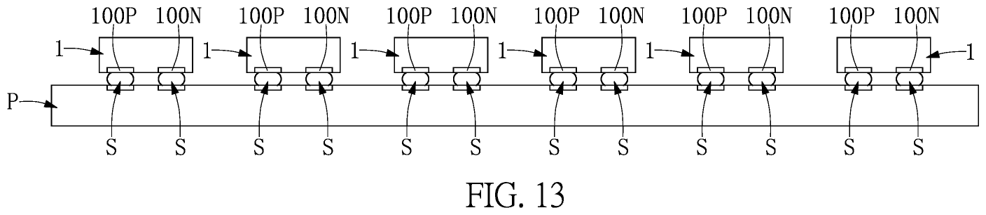

Referring to FIG. 1 to FIG. 11, a first embodiment of the present disclosure provides a chip transferring method including the following steps: firstly, referring to FIG. 1 and FIG. 2, randomly distributing a plurality of LED chip structures C in a liquid substance L of a liquid receiving tank G each of the LED chip structures C including an LED chip 1, a metal material layer 3 and a removable connection layer 2 connected between the LED chip 1 and the metal material layer 3 (step S100); next, referring to FIG. 1 and FIG. 6 to FIG. 11, transferring the LED chip structure C from the liquid receiving tank G to an adhesive substrate H by adhering of a carrier substrate E (step S102); then, referring to FIG. 10 and FIG. 11, removing the removable connection layer 2 by a material removing module R so as to separate the metal material layer 3 from the LED chip 1 (step S104); afterwards, referring to FIG. 11 and FIG. 12, transferring the LED chip 1 from the adhesive substrate H to a circuit substrate P (step S106); and then referring to FIG. 1 and FIG. 13, electrically connecting the LED chip 1 to the circuit substrate P (step S108).

For example, referring to FIG. 2 to FIG. 4, the LED chip 1 includes two electrode contacts 100 (such as a first electrode contact and a second electrode contact) disposed on a top side thereof, the removable connection layer 2 is disposed on a bottom side of the LED chip 1, and the metal material layer 3 is disposed on the removable connection layer 2. More particularly, a bottom side of the LED chip 1 can be completely or partially covered by the removable connection layer 2, and a bottom side of the removable connection layer 2 can be completely or partially covered by the metal material layer 3. Therefore, when the LED chip structures C are concurrently placed in the liquid substance L (such as water or any mixing liquid containing water) of the liquid receiving tank G, the liquid substance L can be vibrated or shaken by a shock wave (or any external force), so that the LED chip structures C can be randomly distributed in the liquid substance L of the liquid receiving tank G However, the aforementioned description is merely an example and is not meant to limit the scope of the present disclosure.

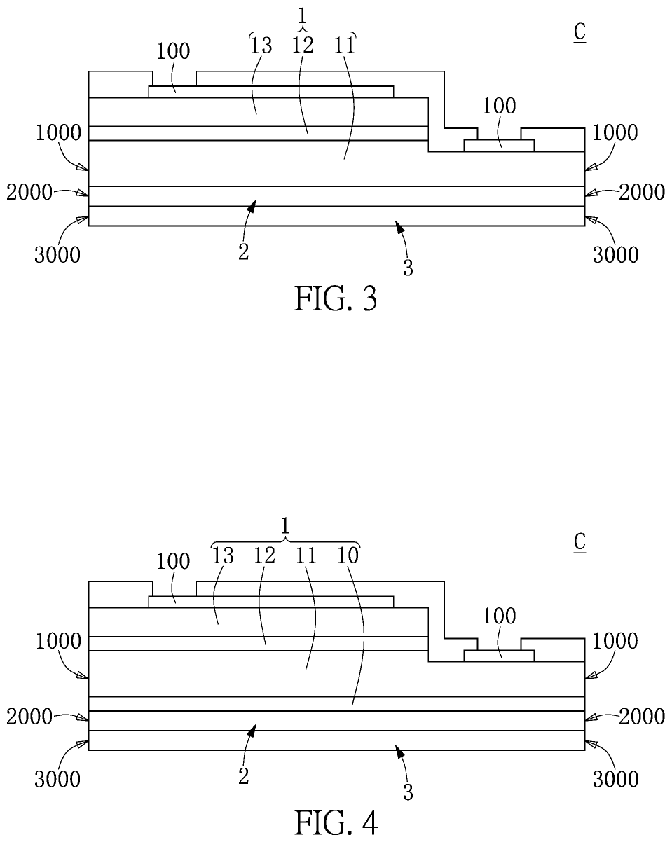

For example, referring to FIG. 3, the LED chip 1 can be a micro LED chip without a base. The micro LED chip includes a p-type semiconductor layer 11, a light-emitting layer 12 disposed on the p-type semiconductor layer 11, and an n-type semiconductor layer 13 disposed on the light-emitting layer 12, and the two electrode contacts 100 of the LED chip 1 are respectively electrically connected to the p-type semiconductor layer 11 and the n-type semiconductor layer 13. However, the aforementioned description is merely an example and is not meant to limit the scope of the present disclosure.

For example, referring to FIG. 4, the LED chip 1 can be a mini LED chip. The mini LED chip includes a base layer 10, a p-type semiconductor layer 11 disposed on the base layer 10, a light-emitting layer 12 disposed on the p-type semiconductor layer 11, and an n-type semiconductor layer 13 disposed on the light-emitting layer 12, and the two electrode contacts 100 of the LED chip 1 are respectively electrically connected to the p-type semiconductor layer 11 and the n-type semiconductor layer 13. However, the aforementioned description is merely an example and is not meant to limit the scope of the present disclosure.

For example, as shown in FIG. 3 or FIG. 4, the LED chip structures C can be prefabricated on the same wafer, and then the LED chip structures C can be separated from each other by cutting the wafer. Hence, as shown in FIG. 3, after cutting the wafer, the lateral sides 1000 of the LED chip 1 are respectively connected to the lateral sides 2000 of the removable connection layer 2, the lateral sides 2000 of the removable connection layer 2 are respectively connected to the lateral sides 3000 of the metal material layer 3, and all of the lateral sides 1000 of the LED chip 1, the lateral sides 2000 of the removable connection layer 2 and the lateral sides 3000 of the metal material layer 3 are cutting surfaces that are flush with each other. However, the aforementioned description is merely an example and is not meant to limit the scope of the present disclosure.

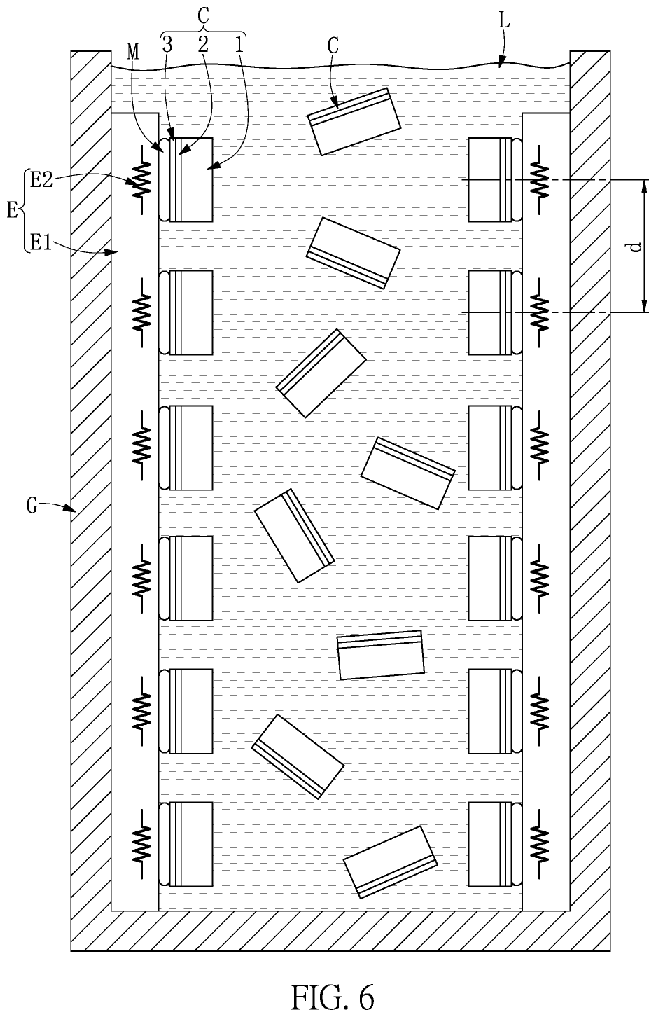

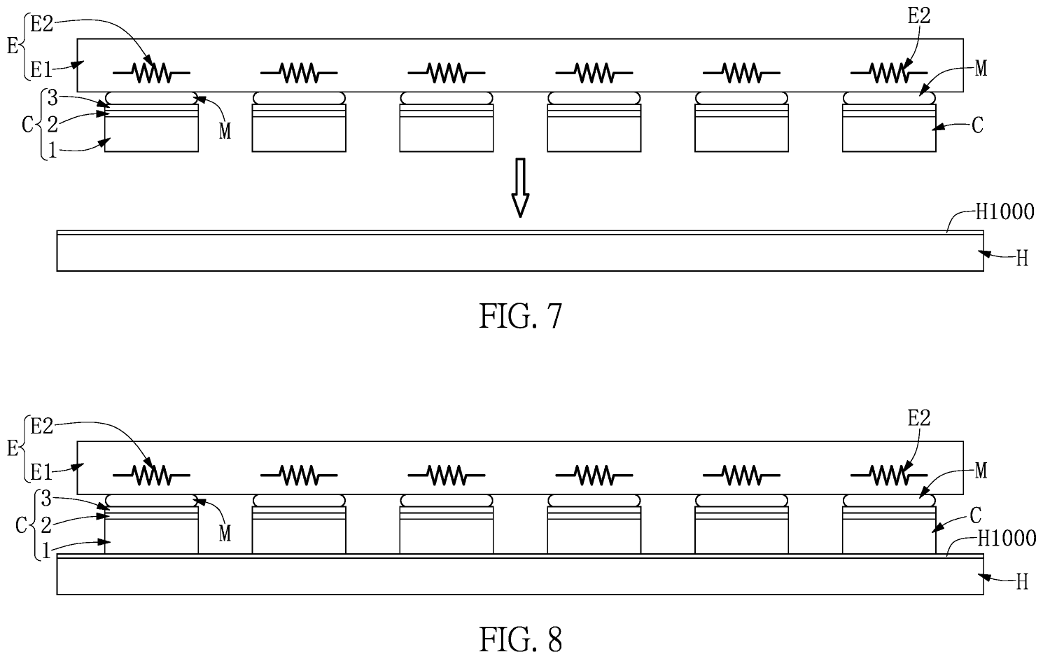

For example, referring to FIG. 2, FIG. 6 and FIG. 7, the carrier substrate E includes a carrier body E1 for carrying a plurality of hot-melt material layers M and a plurality of micro heaters E2 disposed on or inside the carrier body E1, and the carrier substrate E can be movably disposed in the liquid receiving tank G (as shown in FIG. 6) or separated from the liquid receiving tank G (as shown FIG. 7). It should be noted that the hot-melt material layer M can be a low-temperature solder or any solder material that can be melted at a low temperature (that is to say, the hot-melt material layer M has a low melting point). The low melting point can range from 10 to 40° C. (or from 5 to 30° C., or from 20 to 50° C.) or cannot exceed 178° C. For example, the value of the low melting point can be an arbitrary non-positive integer or an arbitrary positive integer. More particularly, as shown in FIG. 6, when the carrier substrate E is placed in the liquid receiving tank G the micro heaters E2 can be turned on (heated) so as to respectively melt the hot-melt material layers M (a viscosity of each hot-melt material layer M can be increased by heating of at least one corresponding micro heater E2), so that the metal material layers 3 of the LED chip structures C can be respectively adhered to the melted hot-melt material layers M so as to respectively position the positions of the LED chip structures C relative to the carrier body E1. That is to say, when the carrier substrate E is placed in the liquid receiving tank G the LED chip structures C can be respectively adhered to the hot-melt material layers M due to the viscosity of the hot-melt material layers M that have been melted. Hence, when the carrier substrate E is placed in the liquid receiving tank G, the hot-melt material layers M can be respectively melted by heating of the micro heaters E2, and the metal material layer 3 of each of the LED chip structures C can be adhered to the corresponding hot-melt material layer M that has been melted. However, the aforementioned description is merely an example and is not meant to limit the scope of the present disclosure.

For example, referring to FIG. 7 and FIG. 8, when the carrier substrate E that has the LED chip structures C adhered thereto is separated from the liquid receiving tank G, the LED chip structures C that are respectively adhered to the hot-melt material layers M can be moved onto an adhesive layer H1000 of an adhesive substrate H by carrying of the carrier body E1. However, the aforementioned description is merely an example and is not meant to limit the scope of the present disclosure.

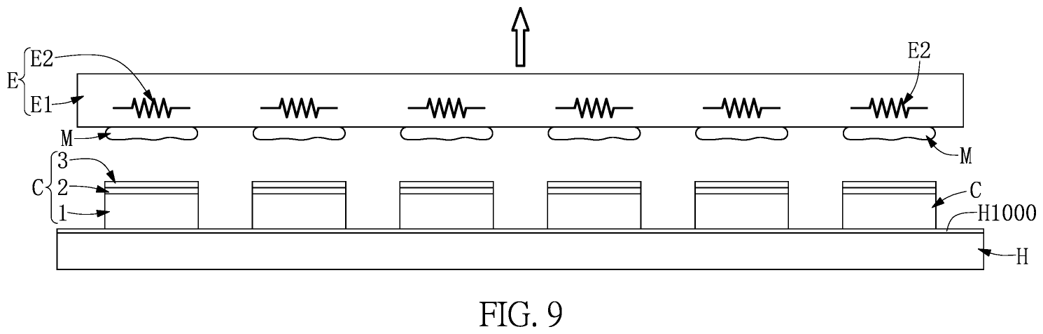

For example, referring to FIG. 8 and FIG. 9, after the LED chips 1 are disposed on the adhesive layer H1000 of the adhesive substrate H, the hot-melt material layers M can be respectively heated again by the micro heaters E2 (a viscosity of each hot-melt material layer M can be increased by heating of the at least one corresponding micro heater E2), so that when the carrier body E1 is moved upwards far away from the LED chip structures C, the metal material layers 3 of the LED chip structures C can be respectively released (or separated) from the adhesive hot-melt material layers M. In addition, as shown in FIG. 8, in another embodiment, when the removable connection layers 2 are removed firstly, the metal material layers 3, the hot-melt material layers M and the carrier substrate E can be concurrently separated from the LED chips 1 due to removal of the removable connection layers 2. However, the aforementioned description is merely an example and is not meant to limit the scope of the present disclosure.

For example, referring to FIG. 10 and FIG. 11, when the carrier substrate E is separated from the LED chips 1, the removable connection layers 2 (such as light resistance layers made of any photosensitive material or light sensitive material) can be removed by a photoresist stripping solution R100 (such as an organic solvent or an inorganic solvent) provided by a material removing module R (such as a photoresist stripper providing device), so that the metal material layers 3 can be respectively separated from the LED chips 1 following the removal of the removable connection layers 2. That is to say, because the removable connection layer 2 is connected between the LED chip 1 and the metal material layer 3, the metal material layers 3 can be respectively separated from the LED chips 1 while removing the removable connection layers 2. However, the aforementioned description is merely an example and is not meant to limit the scope of the present disclosure.

For example, referring to FIG. 3 or FIG. 4, the two electrode contacts can be a first electrode contact P100 and a second electrode contact 100N that are respectively electrically connected to the p-type semiconductor layer 11 and the n-type semiconductor layer 13. Referring to FIG. 11 and FIG. 12, each of the LED chips 1 can be classified according to the positions of the first electrode contact P100 and the second electrode contact 100N. When the first electrode contact P100 and the second electrode contact 100N are respectively placed on a left side and a right side of the LED chip 1, the LED chip 1 with the first left electrode contact P100 and the second right electrode contact 100N can be transferred from the adhesive substrate H to a first auxiliary adhesive substrate H1. When the first electrode contact P100 and the second electrode contact 100N are respectively placed on the right side and the left side of the LED chip 1, the LED chip 1 with the first right electrode contact P100 and the second left electrode contact 100N can be transferred from the adhesive substrate H to a second auxiliary adhesive substrate H2. More particularly, after the step of removing the removable connection layer 2 so as to separate the metal material layer 3 from the LED chip 1, the method further includes: firstly, using an optical detection module (not shown) to identify a first electrode contact 100P and a second electrode contact 100N of each of the LED chips 1 so as to obtain position information of the first electrode contact 100P and the second electrode contact 100N of each of the LED chips 1 (for example, the adhesive substrate H can be a light-permitting substrate, so that the optical detection module can see the first electrode contact 100P and the second electrode contact 100N through the adhesive substrate H); next, using a nozzle (not shown) or any chip-transferring device to transfer the LED chip 1 from the adhesive substrate H to a first auxiliary adhesive substrate H1 or a second auxiliary adhesive substrate H2 according to the position information of the first electrode contact 100P and the second electrode contact 100N of each of the LED chips 1; and then transferring the LED chip 1 from the first auxiliary adhesive substrate H1 or the second auxiliary adhesive substrate H2 to the circuit substrate P. However, the aforementioned description is merely an example and is not meant to limit the scope of the present disclosure.

For example, when the position information is “the first electrode contact P100 and the second electrode contact 100N being respectively placed on the left side and the right side of the LED chip 1”, the LED chip 1 is transferred from the adhesive substrate H to the first auxiliary adhesive substrate H1 (as shown by a top right corner region in FIG. 12). When the position information is “the first electrode contact P100 and the second electrode contact 100N being respectively placed on the right side and the left side of the LED chip 1”, the LED chip 1 is transferred from the adhesive substrate H to the second auxiliary adhesive substrate H2 (as shown by a bottom right corner region in FIG. 12). However, the aforementioned description is merely an example and is not meant to limit the scope of the present disclosure.

For example, referring to FIG. 12 and FIG. 13, the LED chips 1 that are disposed on the first auxiliary adhesive substrate H1 or the second auxiliary adhesive substrate H2 can be transferred to the circuit substrate P by the nozzle (not shown) or any chip-transferring device, and the first electrode contact P100 and the second electrode contact 100N of each of the LED chips 1 can be electrically connected to the circuit substrate P respectively through two solder balls (for example, the LED chip 1 can be bonded to the circuit substrate P by reflow soldering or laser bonding). However, the aforementioned description is merely an example and is not meant to limit the scope of the present disclosure.

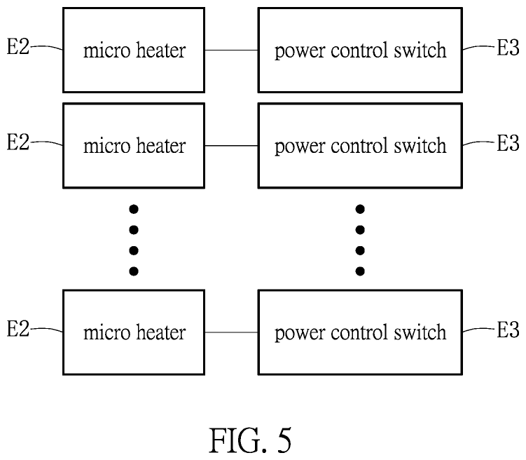

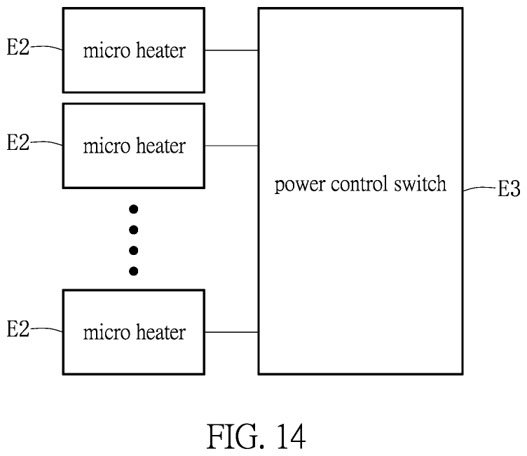

For example, as shown in FIG. 5, the carrier substrate E includes a plurality of power control switches E3, and the power control switch E3 can be a semiconductor switch (such as a CMOS (complementary metal oxide semiconductor) switch) or a MEMS (microelectromechanical systems) switch. In addition, the power control switches E3 can be respectively electrically connected to the micro heaters E2, and each of the power control switches E3 can be turned on so as to drive the corresponding micro heater E2 to heat the corresponding hot-melt material layer M. That is to say, each of the micro heaters E2 can be turned on or off by driving of the corresponding power control switch E3, and each of the hot-melt material layers M can be heated while the corresponding micro heater E2 is turned on. In another embodiment, as shown in FIG. 14, the carrier substrate E includes a power control switch E3, and the power control switch E3 is electrically connected to the micro heaters E2, and the power control switch E3 can be turned on so as to drive the micro heaters E2 to respectively heat the hot-melt material layers M. That is to say, all or part of the micro heaters E2 can be concurrently turned on or off by driving of the power control switch E3. However, the aforementioned description is merely an example and is not meant to limit the scope of the present disclosure. For example, as shown in FIG. 2, the micro heaters E2 can be arranged as a matrix, and each of the micro heaters E2 can be movably or fixedly disposed on the carrier body E1. When each of the micro heaters E2 is movably disposed on the carrier body E1, a distance d between the two adjacent hot-melt material layers M can be adjusted. That is to say, when a distance between the two adjacent LED chips 1 has been adjusted (or changed), the distance d between the two adjacent hot-melt material layers M can be adjusted along a track according to the adjusted distance between the two adjacent LED chips 1, so that the distance between the two adjacent LED chips 1 is just equal to the distance d between the two adjacent hot-melt material layers M. However, the aforementioned description is merely an example and is not meant to limit the scope of the present disclosure.

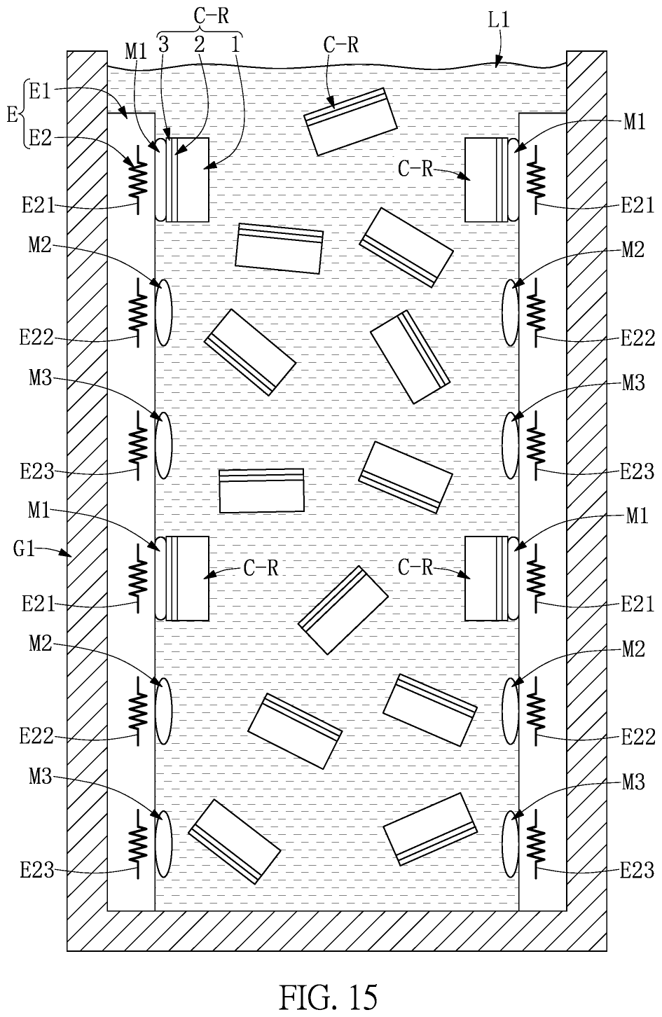

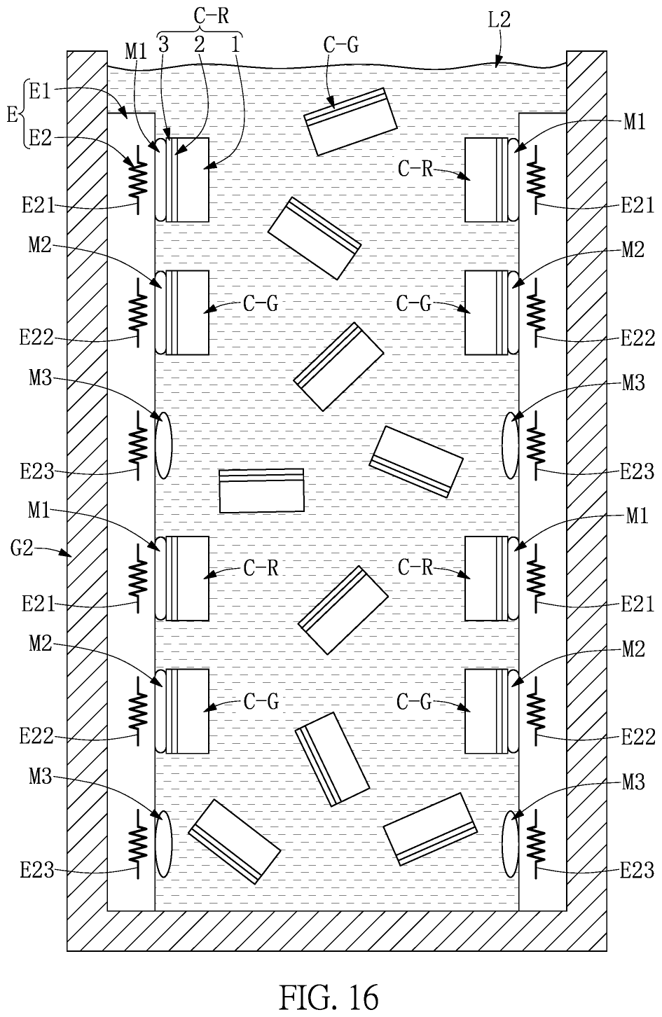

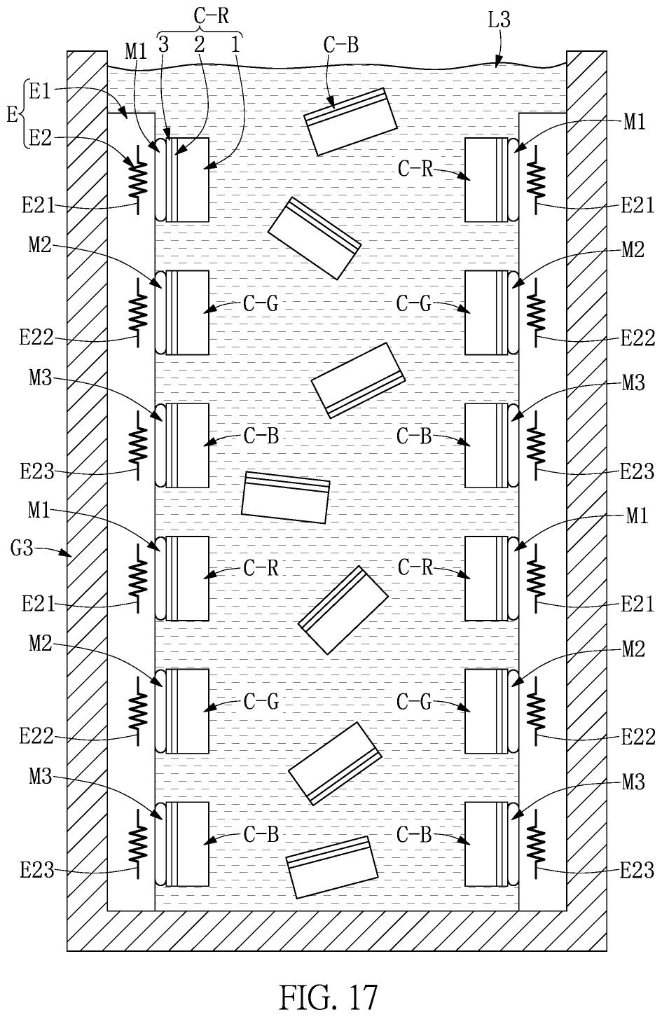

For example, referring to FIG. 15 to FIG. 17, the LED chip structures C can be divided into a plurality of red LED chip structures (C-R), a plurality of green LED chip structures (C-G) and a plurality of blue LED chip structures (C-B), the micro heaters E2 can be divided into a plurality of first micro heaters E21, a plurality of second micro heaters E22 and a plurality of third micro heaters E23, and the hot-melt material layers M can be divided into a plurality of first hot-melt material layers M1, a plurality of second hot-melt material layers M2 and a plurality of third hot-melt material layers M3. As shown in FIG. 15, when the red LED chip structures (C-R) are randomly distributed in a first liquid substance L1 of a first liquid receiving tank G1, a viscosity of each of the first hot-melt material layers M1 can be increased by heating of the corresponding first micro heater E21, so that the red LED chip structures (C-R) can be respectively adhered to the first hot-melt material layers M1. As shown in FIG. 16, when the green LED chip structures (C-G) are randomly distributed in a second liquid substance L2 of a second liquid receiving tank G2, a viscosity of each of the second hot-melt material layers M2 can be increased by heating of the corresponding second micro heater E22, so that the green LED chip structures (C-G) can be respectively adhered to the second hot-melt material layers M2. As shown in FIG. 17, when the blue LED chip structures (C-B) are randomly distributed in a third liquid substance L3 of a third liquid receiving tank G3, a viscosity of each of the third hot-melt material layers M3 can be increased by heating of the corresponding third micro heater E23, so that the blue LED chip structures (C-B) can be respectively adhered to the third hot-melt material layers M1. Hence, the red LED chip structures (C-R), the green LED chip structures (C-G) and the blue LED chip structures (C-B) can be sequentially adhered to the carrier substrate E. However, the aforementioned description is merely an example and is not meant to limit the scope of the present disclosure.

### Second Embodiment

Referring to FIG. 2 to FIG. 14, a second embodiment of the present disclosure provides a chip transferring system including a liquid receiving tank G, a carrier substrate E and a material removing module R.

More particularly, as shown in FIG. 2, the liquid receiving tank G includes a liquid substance L received therein, and a plurality of LED chip structures C can be randomly distributed in the liquid substance L of the liquid receiving tank G. In addition, each LED chip structure includes an LED chip 1, a removable connection layer 2 and a metal material layer 3. The LED chip 1 includes two electrode contacts 100 disposed on a top side thereof, the removable connection layer 2 is disposed on a bottom side of the LED chip 1, and the metal material layer 3 is disposed on the removable connection layer 2.

More particularly, referring to FIG. 2 and FIG. 6 to FIG. 8, the carrier substrate E includes a carrier body E1 for carrying a plurality of hot-melt material layers M and a plurality of micro heaters E2 disposed on or inside the carrier body E1. In addition, referring to FIG. 7 to FIG. 13, the carrier substrate E can be movably disposed in the liquid receiving tank G (as shown in FIG. 6) or separated from the liquid receiving tank G (as shown FIG. 7), the LED chip structures C can be transferred from the liquid receiving tank G to an adhesive substrate H through adhesion provided by the carrier substrate E, and the LED chip structures C can be transferred from the adhesive substrate H (such as a first auxiliary adhesive substrate H1 or a second auxiliary adhesive substrate H2) to a circuit substrate P.

More particularly, referring to FIG. 2 and FIG. 6 to FIG. 8, the material removing module R is disposed above the LED chip structures C. For example, when the LED chip structures C are transferred to the adhesive substrate H, the removable connection layers 2 (such as light resistance layers) can be removed by a photoresist stripping solution R100 provided by the material removing module R (such as a photoresist stripper providing device), so that the metal material layers 3 can be respectively separated from the LED chips 1 following the removal of the removable connection layers 2. That is to say, because the removable connection layer 2 is connected between the LED chip 1 and the metal material layer 3, the metal material layers 3 can be respectively separated from the LED chips 1 while removing the removable connection layers 2. However, the aforementioned description is merely an example and is not meant to limit the scope of the present disclosure.

For example, as shown in FIG. 2, the micro heaters E2 can be arranged as a matrix, and each of the micro heaters E2 can be movably or fixedly disposed on the carrier body E1. When each of the micro heaters E2 is movably disposed on the carrier body E1, a distance d between the two adjacent hot-melt material layers M can be adjusted. That is to say, when a distance between the two adjacent LED chips 1 has been adjusted (or changed), the distance d between the two adjacent hot-melt material layers M can be adjusted along a track according to the adjusted distance between the two adjacent LED chips 1, so that the distance between the two adjacent LED chips 1 is just equal to the distance d between the two adjacent hot-melt material layers M. However, the aforementioned description is merely an example and is not meant to limit the scope of the present disclosure.

For example, as shown in FIG. 5, the carrier substrate E includes a plurality of power control switches E3, and the power control switch E3 can be a semiconductor switch (such as a CMOS switch) or a MEMS switch. In addition, the power control switches E3 can be respectively electrically connected to the micro heaters E2, and each of the power control switches E3 can be turned on so as to drive the corresponding micro heater E2 to heat the corresponding hot-melt material layer M. That is to say, each of the micro heaters E2 can be turned on or off by driving of the corresponding power control switch E3, and each of the hot-melt material layers M can be heated while the corresponding micro heater E2 is turned on. In another embodiment, as shown in FIG. 14, the carrier substrate E includes a power control switch E3, and the power control switch E3 is electrically connected to the micro heaters E2, and the power control switch E3 can be turned on so as to drive the micro heaters E2 to respectively heat the hot-melt material layers M. That is to say, all or part of the micro heaters E2 can be concurrently turned on or off by driving of the power control switch E3. However, the aforementioned description is merely an example and is not meant to limit the scope of the present disclosure.

### Beneficial Effects of the Embodiments

In conclusion, by virtue of “the removable connection layer 2 being disposed on a bottom side of the LED chip 1” and “the metal material layer 3 being disposed on the removable connection layer 2”, the metal material layers 3 can be respectively separated from the LED chips 1 while removing the removable connection layers 2.

Furthermore, by virtue of “a plurality of LED chip structures C being randomly distributed in the liquid substance L of the liquid receiving tank G”, “the carrier substrate E being movably disposed in the liquid receiving tank G or separated from the liquid receiving tank G” and “the material removing module R being disposed above the LED chip structures C”, the removable connection layers 2 can be removed by the material removing module R, so that the metal material layers 3 can be respectively separated from the LED chips 1 following the removal of the removable connection layers 2. In addition, the micro heaters E2 can be turned on so as to respectively melt the hot-melt material layers M, so that the metal material layers 3 of the LED chip structures C can be respectively adhered to the hot-melt material layers M.

Moreover, by virtue of “randomly distributing a plurality of LED chip structures C in a liquid substance L of a liquid receiving tank G”, “transferring the LED chip structure C from the liquid receiving tank G to an adhesive substrate H by adhering of a carrier substrate E”, “removing the removable connection layer 2 by a material removing module R so as to separate the metal material layer 3 from the LED chip 1”, “transferring the LED chip 1 from the adhesive substrate H to a circuit substrate P” and “electrically connecting the LED chip 1 to the circuit substrate P”, the LED chip structures C can be transferred from the liquid receiving tank G to the circuit substrate P by cooperation of the carrier substrate E and the adhesive substrate H, and the metal material layers 3 can be respectively separated from the LED chips 1 following the removal of the removable connection layers 2. In addition, the micro heaters E2 can be turned on so as to respectively melt the hot-melt material layers M, so that the metal material layers 3 of the LED chip structures C can be respectively adhered to the hot-melt material layers M.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A chip transferring method, comprising:
distributing a plurality of LED chip structures in a liquid substance of a liquid receiving tank, wherein each of the LED chip structures includes an LED chip, a metal material layer and a removable connection layer connected between the LED chip and the metal material layer;
placing a carrier substrate in the liquid receiving tank, wherein the carrier substrate includes a carrier body for carrying a plurality of hot-melt material layers and a plurality of micro heaters disposed on or inside the carrier body;
respectively melting the hot-melt material layers by heating of the micro heaters, so that the metal material layer of each of the LED chip structures is adhered to the corresponding hot-melt material layer that has been melted;
separating the carrier substrate with the LED chip structures from the liquid receiving tank; and
transferring the LED chip structures from the carrier substrate to an adhesive substrate.

2. The chip transferring method according to claim 1, wherein, after the step of transferring the LED chip structures from the carrier substrate to the adhesive substrate, the method further comprises:
respectively heating the hot-melt material layers by the micro heaters; and
respectively separating the hot-melt material layers from the metal material layers of the LED chip structures.

3. The chip transferring method according to claim 2, wherein, after the step of respectively separating the hot-melt material layers from the metal material layers of the LED chip structures, the method further comprises:
removing the removable connection layer so as to separate the metal material layer from the LED chip;
transferring the LED chip from the adhesive substrate to a circuit substrate; and
electrically connecting the LED chip to the circuit substrate.

4. The chip transferring method according to claim 3, wherein, after the step of removing the removable connection layer so as to separate the metal material layer from the LED chip, the method further comprises:
identifying a first electrode contact and a second electrode contact of each of the LED chips, so as to obtain position information of the first electrode contact and the second electrode contact of each of the LED chips;
transferring the LED chip from the adhesive substrate to a first auxiliary adhesive substrate or a second auxiliary adhesive substrate according to the position information of the first electrode contact and the second electrode contact of each of the LED chips; and
transferring the LED chip from the first auxiliary adhesive substrate or the second auxiliary adhesive substrate to the circuit substrate.

5. The chip transferring method according to claim 4, wherein the first electrode contact and the second electrode contact are disposed on a top side of the LED chip, and the removable connection layer is disposed on a bottom side of the LED chip.

6. An LED chip structure, comprising:
an LED chip including at least one electrode contact disposed thereon;
a removable connection layer disposed on the LED chip; and
a metal material layer disposed on the removable connection layer.

7. The LED chip structure according to claim 6, wherein the removable connection layer is connected between the LED chip and the metal material layer, so that the metal material is separated from LED chip when the removable connection layer is removed.

8. The LED chip structure according to claim 6, wherein a bottom side of the LED chip is completely covered by the removable connection layer, and a bottom side of the removable connection layer is completely covered by the metal material layer.

9. The LED chip structure according to claim 6, wherein the LED chip structure is applied to a carrier substrate, and the carrier substrate includes a carrier body for carrying a plurality of hot-melt material layers and a plurality of micro heaters disposed on or inside the carrier body.

10. The LED chip structure according to claim 6, wherein the at least one electrode contact is disposed on a top side of the LED chip, and the removable connection layer is disposed on a bottom side of the LED chip.
